(19) United States
(12) Patent Application Publication
(10) Pub. No.: US 2007/0267642 A1
(43) Pub. Date: Nov. 22, 2007

(54) Light-emitting devices and methods for manufacturing the same

(75) Inventors: Alexei A, Erchak, Cambridge, MA (US); Christian Hoepfner, North Andover, MA (US); Paul Panaccione, Newburyport, MA (US)

Correspondence Address: LUMINUS DEVICES , INC.;C/O WOLF, GREENFIELD & SACKS , P.C., 600 ATLANTIC AVENUE, BOSTON, MA, 02210-2206, US

(73) Assignee: Luminus Devices, Inc., Woburn, MA (US)

(21) Appl. No.: 11/521,092

(22) Filed: Sep. 14, 2006

Related U.S. Application Data
(60) Provisional application No. 60/801,230, filed on May 16, 2006.

(51) Int. Cl. H01L 33/00

(52) U.S. Cl. 257/98

(57) ABSTRACT

Light-emitting device assemblies are described. The assemblies can include a light-emitting device, an optional package supporting the light-emitting device, and a base supporting the light-emitting device or the optional package. The base may include a protrusion extending in the direction of the light-emitting device. The thermally conductive pathway can extend between the light-emitting device and the base, such that the thermally conductive pathway includes the protrusion. Other assemblies can include a light-emitting device, a support substrate, and a layer of dielectric material on the support substrate. An aperture may be defined by the dielectric material through which a thermally conductive material (e.g., a portion of the support substrate) can extend to facilitate thermal communication between the support substrate and the light-emitting device. Thermal communication between the support substrate and the light-emitting device can increase the removal of thermal energy generated by the device.

### RELATED APPLICATIONS

This application claims priority under 35 U.S.C. § 119(e) to U.S. Provisional Application Ser. No. 60/801,230, filed on May 16, 2006, which is herein incorporated by reference in its entirety.

### FIELD

The present embodiments relate generally to light-emitting devices, and more particularly to light-emitting device assemblies that include light-emitting diodes (LEDs) as light sources. Specifically, the methods and systems of at least some of the embodiments include those that increase the removal of thermal energy generated by the device.

### BACKGROUND

A light-emitting diode (LED) can often provide light in a more efficient manner than an incandescent light source and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays. Many technological advances have led to the development of high power LEDs by increasing the amount of light emission from such devices.

Typically, an LED is formed of multiple layers, with at least some of the layers being formed of different materials. In general, the materials and thicknesses selected for the layers influence the wavelength(s) of light emitted by the LED. In addition, the chemical composition of the layers can be selected to promote isolation of injected electrical charge carriers into regions (commonly referred to as quantum wells) for relatively efficient conversion to optical power. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

LEDs also generally include contact structures (also referred to as electrical contact structures or electrodes), which are features on a device that may be electrically connected to a power source. The power source can provide current to the device via the contact structures, e.g., the contact structures can deliver current along the lengths of structures to the surface of the device within which energy can be converted into light.

The layers of semiconductor material of the LED are typically disposed on a supporting base (e.g., a core board). In certain LEDs, a layer of dielectric material is disposed between the multiple layers of semiconductor material and a thermally conductive substrate of the supporting base, such that the semiconductor material layers of the LED are electrically isolated from the thermally conductive substrate.

In some high power light-emitting devices, problems may arise with managing the thermal energies generated by the light-emitting devices, which may decrease the lifespan of the device. Accordingly, light-emitting devices that effectively dissipate heat can be beneficial.

### SUMMARY

Light-emitting devices, and related components, systems, and methods associated therewith are provided.

In one aspect, a light-emitting device assembly is provided. The assembly comprises a light-emitting device and a base supporting the light-emitting device. The base comprises a protrusion extending in the direction of the light-emitting device. A thermally conductive pathway extends between the light-emitting device and the base, such that the thermally conductive pathway includes the protrusion.

In another aspect, a light-emitting device assembly is provided. The assembly comprises a light-emitting device and a base. The base comprises an electrically insulating portion and a thermally conductive portion. The electrically insulating portion of the base comprises an electrically insulating material layer, and the electrically insulating material layer is disposed over a portion of the thermally conductive portion of the base. A thermally conductive pathway extends between the light-emitting device and the thermally conductive portion of the base.

In another aspect, a light-emitting device assembly is provided. The assembly comprises a light-emitting device and a support substrate. A dielectric material layer is disposed on the support substrate and defines an aperture, and a thermally conductive pathway extends through the aperture from the support substrate to the light-emitting device.

In another aspect, a light-emitting device assembly is provided. The assembly comprises a light-emitting device and a base. The base comprises a first region having a first thermal conductivity and a second region having a second thermal conductivity, wherein the first thermal conductivity is larger that the second thermal conductivity. The second region defines an aperture within which at least a portion of the first region resides. A thermally conductive pathway extends between the first region of the base and the light-emitting device.

In one aspect, a method of fabricating a light-emitting device assembly is provided. The method comprises providing a base comprising a thermally conductive portion, wherein the thermally conductive portion of the base comprises a protrusion. The method further comprises providing a light-emitting device and forming a thermally conductive pathway that extends between the light-emitting device and the thermally conductive portion of the base, such that the thermally conductive pathway includes the protrusion.

Other aspects, embodiments and features of the invention will become apparent from the following detailed description of the invention when considered in conjunction with the accompanying figures. The accompanying figures are schematic and are not intended to be drawn to scale. In the figures, each identical or substantially similar component that is illustrated in various figures is represented by a single numeral or notation.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF DRAWINGS

FIG. 1A is a side view schematic of a representative light-emitting device assembly in accordance with one embodiment;

FIG. 1B is a top view schematic of a base in a light-emitting device assembly in accordance with one embodiment;

FIGS. 2A-2C are schematics illustrating the formation of a base including a protrusion for a light-emitting device assembly in accordance with one embodiment;

FIGS. 3A-3C are schematics illustrating the formation of a base including a protrusion for a light-emitting device assembly in accordance with one embodiment;

FIGS. 4A-4C are schematics illustrating the formation of a base including a protrusion for a light-emitting device assembly in accordance with one embodiment;

FIG. 5 is a side view schematic of a representative light-emitting device assembly in accordance with one embodiment;

FIG. 6 is a side view schematic of a representative light-emitting device assembly in accordance with one embodiment;

FIG. 7 is a side view schematic of a representative light-emitting device assembly in accordance with one embodiment;

FIG. 8 is a side view schematic of a representative light-emitting device assembly in accordance with one embodiment; and

FIG. 9 is a side view of an LED in accordance with one embodiment.

### DETAILED DESCRIPTION

One or more embodiments presented herein include a light-emitting device assembly which has been configured to effectively transfer thermal energy generated by a light-emitting device (e.g., an LED) to a supporting base (e.g., a core board) and ultimately to the surroundings, which may include an external heat sink. Such an assembly can include a light-emitting device, an optional package that can support the light-emitting device, and a base supporting the package. Alternatively, the package may be absent, and the base may directly support the light-emitting device (e.g., an LED die). The base may include a layer (e.g., a dielectric layer) on a substrate, wherein the substrate may be thermally conductive and/or electrically conductive. The layer may be a dielectric layer that can electrically isolate the substrate from other features (e.g., metal contacts) of the assembly. An aperture may be defined by the layer through which a thermally conductive material (e.g., a portion of the substrate) can extend to facilitate thermal communication between the substrate and the light-emitting device. The thermal communication with the light-emitting device can increase the removal of thermal energy generated by the light-emitting device.

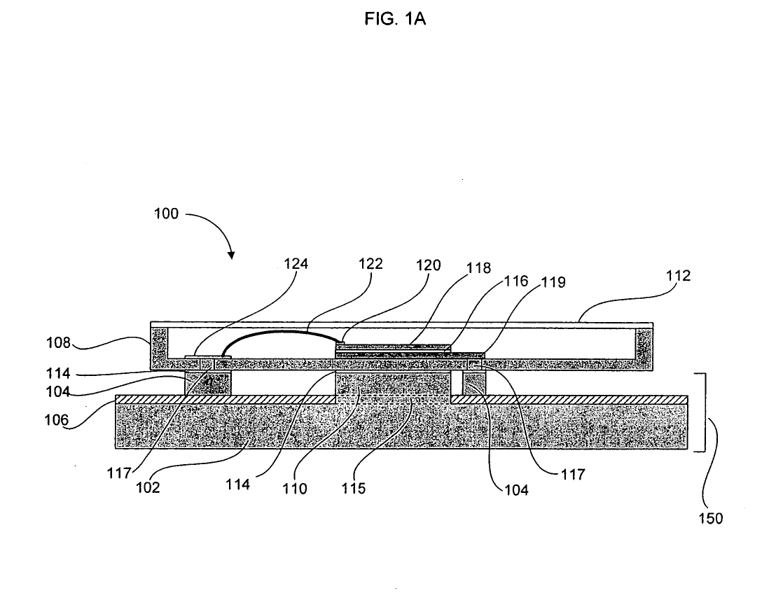

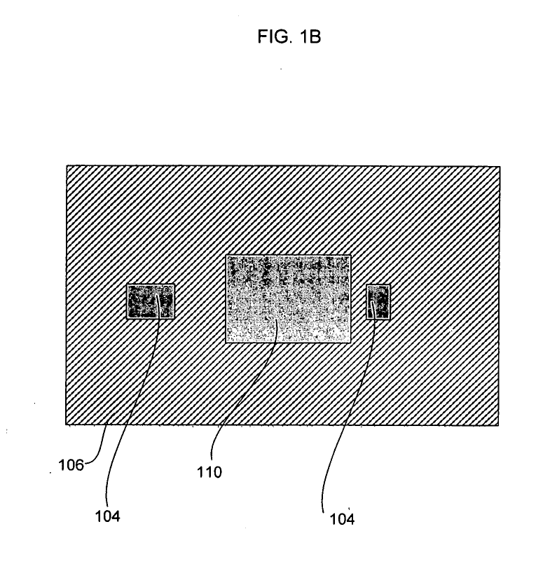

FIG. 1A shows a light-emitting device assembly 100 which may include a base 150 (e.g., a core board) supporting a package 108 that in turn supports a light-emitting die 118, in accordance with one embodiment. As referred to herein, the base may include the substrate and any layer or plurality of layers that may be disposed on part or all of the substrate area (e.g., one or more layers of dielectric material, one or more electrical contact layers). As shown in the illustration of FIG. 1, the base 150 may include a substrate 102 supporting a layer 106, in accordance with one embodiment. In some embodiments, layer 106 is an electrically insulating layer, such as a dielectric material layer. Layer 106 may be bonded to, or otherwise formed on, the substrate 102 in any suitable manner including through self-adhesive or bonding means. In some embodiments, the layer 106 may be affixed to the substrate 102 through adhesive material such as an epoxy type material.

Layer 106 can define an aperture 115, where the aperture 115 can enable a thermally conductive pathway to extend from the substrate 102 to the light-emitting die 118. The light-emitting die can be in direct or indirect thermal contact with the thermally conductive pathway that extends from the substrate, for example indirect thermal contact may result when the light-emitting die is supported by a package. The thermally conductive pathway between the light-emitting die 118 and the substrate 102 can have a minimum thermal conductivity of greater than about 25 W/m*K, greater than about 50 W/m*K, greater than about 100 W/m*K, or greater than about 200 W/m*K (e.g., about 400 W/m*K), thus increasing heat removal from the light-emitting device via substrate 102.

The thermally conductive pathway may include protrusion 110 that extends through the aperture, such that protrusion 110 may be disposed between the light-emitting die 118 and the substrate 102. Protrusion 110 may be any suitable localized feature that extends upwards from the substrate 102, and can have any suitable shape and dimensions, as the techniques described herein are not limited in this respect. In some embodiments, protrusion 110 is part of substrate 102 and protrudes upward through the aperture 115 in layer 106. In other embodiments, protrusion 110 may be formed of a thermally conductive material different than the material of the substrate 102 and may extend through the aperture 115 to contact the substrate 102 and form a part of the thermally conductive pathway. Protrusion 110 may be elevated with respect to layer 106, may be flush with layer 106, or may be recessed with respect to layer 106. When protrusion 110 is recessed with respect to layer 106, a thermally conductive filler material and/or attachment material (e.g., a solder) may be disposed on protrusion 110.

At least one electrical contact 104 may be supported by layer 106. Electrical contact(s) 104 can be a component of a circuit board assembly (not shown) that may also be disposed on layer 106. When electrical contact(s) 104 are included in the assembly, layer 106 may be an electrically insulating layer, such as a dielectric layer, which may electrically isolate the electrical contact(s) 104 from the substrate 102. In certain embodiments, the electrical contact(s) 104 and protrusion 110 are flush mount so as to be substantially level with each other and therefore facilitate attachment to package 108. Electrical contact(s) 104 may be connected to an external voltage source (not shown) that can provide power to the device.

Package 108 may have any suitable design and construction. In embodiments in which the package forms part of the thermally conductive pathway between the substrate 102 and light-emitting die 118, part or all of package 108 may be formed of a material having a sufficiently high thermal conductivity. In some cases, the package is formed of a thermally conductive ceramic such as aluminum nitride. The package may be electrically insulating, although it should be appreciated that the techniques presented herein are not limited in this respect. The package may include regions that are electrically insulating and regions that are electrically conductive, for example, vias filled with electrically conductive material (e.g., metal-filled vias, such as tungsten-filled vias) that allow electrical coupling between an exterior surface of the package and an interior surface of the package.

In some embodiments, the package includes a transparent layer 112 which functions as a window to emit light generated by light-emitting die 118. Package 108, as shown in FIG. 1, can be attached to electrical contact 104 and protrusion 110 by any suitable technique, including using an attachment material such as an adhesive or bonding material. For example, package 108 can be attached by solder attach 114. The attachment material may be sufficiently thermally conductive so as to form part of the thermally conductive pathway between the substrate 102 and the light-emitting die 118. In some embodiments, it is preferable that the attachment material is electrically conductive so as to enable electrical coupling therethrough.

One or more light-emitting dies may be fixed to the package 108 with any suitable attachment material 116, including, but not limited to, solder (e.g., an alloy between two or more metals such as gold, germanium, tin, indium, lead, silver, molybdenum, palladium, antimony, zinc, etc.), metal-filled epoxy, thermally conductive adhesives, metallic tape, thermal grease, and/or carbon nanotube-based foams or thin films. Thermally conductive attachment materials typically have a suitably high thermal conductivity and therefore a low thermal resistance per unit contact area. Examples of suitable light-emitting dies that may be fixed to the package are described in further detail below.

Other components and features may be included in the light-emitting device assembly such as n-contact 124, p-contact 119, wire bonds 122, and electrical bond pads 120. N-contact 124 and p-contact 119 may be supported by package 108, while the electrical bond pad(s) 120 can be supported by the light-emitting die 118. Electrical bond pad 120 and n-contact 124 can be electrically coupled to each other through wire bonds 122. In the illustrative embodiment, n-contact 124 and p-contact 119 are respectively electrically connected to electrical contacts 104 by electrically conductive pathways 117 (e.g., formed of a metal, such as tungsten) that extend through vias that may be formed in the package.

Multiple electrical contact pads 120 can be supported on the surface of the light-emitting die. These contact bond pads are features on a device that can be electrically connected to a power source. Contact pads can be designed to improve current distribution in electronic devices such as LEDs. Suitable contact pad structures have been described in U.S. Patent Publication No. 2005-0051785, which is incorporated herein by reference in its entirety and is based on U.S. patent application Ser. No. 10/871,877, entitled “Electronic Device Contact Structures,” filed on Jun. 18, 2004.

Substrate 102 can be comprised of any material that has sufficiently high thermal conductivity. In some embodiments, substrate 102 comprises a metal, such as copper and/or aluminum. In another embodiment, substrate 102 may be a vapor plate, for example, a copper vapor plate, wherein the vapor plate can contain any type of fluid that facilitates the transfer of heat, such as air. Alternatively, or additionally, the substrate 102 may include at least one heat pipe, wherein the heat pipe may be filled or partially filled with a fluid to increase heat transfer and support at least one light-emitting die or light-emitting die package. Additionally, the heat pipe can be coupled to the substrate 102 to increase heat transfer from the light-emitting die via the substrate.

Base 150, which may include substrate 102 and protrusion 110, can facilitate the extraction of thermal energy that may be generated by the light-emitting die 118. Protrusion 110 and substrate 102 can also function as an electrical contact, and may be used in lieu of electrical contact member 104, as discussed below. In some embodiments, it may be preferable for protrusion 110 and substrate 102 to function as an electrical p-contact member, but this configuration is by no way limiting and the protrusion 110 and substrate 102 can also function as an electrical n-contact member.

FIG. 1B illustrates a top view of layer 106 having an aperture disposed over the support substrate (not shown) and protrusion 110 extending through the aperture. The illustration also shows the electrical contacts 104 disposed over layer 106, although it should be appreciated that such electrical contacts may be absent, as the techniques presented herein are not limited in this respect. In one embodiment, layer 106 possesses a thermal conductivity that is less than the thermal conductivity of the protrusion 110. Such an arrangement may result in a base comprising a region having a higher thermal conductivity (e.g., protrusion 110) than an adjacent region (e.g., the region including layer 106). In some embodiments, the thermal conductivity of the higher conductivity region (e.g., protrusion 110) is greater than the thermal conductivity of an adjacent region (e.g., layer 106) by a factor of at least 2, at least 5, at least 10, at least 20, at least 50, or at least 100 (e.g., about 200). As previously described, layer 106 may be an electrically insulating layer, including, but not limited to, a dielectric material layer

It should be appreciated that although the aperture in layer 106 illustrated in FIG. 1 is completely surrounded by layer 106, the techniques presented herein are not limited in this respect. In some embodiments, the aperture may not be completely surrounded by layer 106. For example, the aperture in layer 106 may extend to one or more outer boundaries of layer 106. As such, an aperture as used herein may be defined by any boundary having any open or closed shape. Furthermore, it should also be understood that layer 106 may have a plurality of apertures through which multiple thermally conductive portions extend therethrough. A light-emitting device assembly may include a plurality of light-emitting dies and each die may be disposed over one more thermally conductive regions (e.g., protrusions) adjacent regions of lower thermal conductivity (e.g., layer 106). When a package is included in the assembly, one or more light-emitting dies may be supported by a single or multiple packages which may in turn be supported by one or more thermally conductive regions (e.g., protrusions), so as to establish one or more thermally conductive pathways to the light-emitting dies.

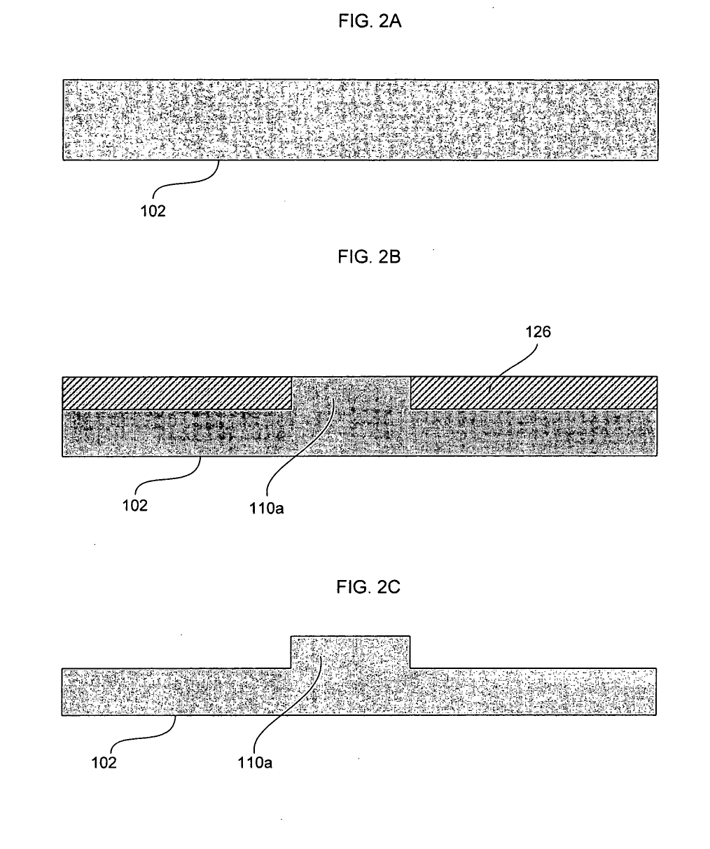

The supporting base structures described herein can be manufactured or fabricated using a variety of methods. Referring to FIGS. 2A-2C, a substrate 102 may be provided, and then a portion of the substrate 102 material 126 may be removed thereby resulting in the formation of a protrusion 110a of material, in accordance with one embodiment. Material 126 may be removed by any suitable process known to those of skill in the art. For example, material 126 may be removed by physically etching away the material and/or by chemically removing the material. In some embodiments, a portion or all of a void in substrate 102 that is created by the removal of material 126 may be filled with any suitable material (e.g., an electrically insulating material, such as a dielectric material), although it should be appreciated that the techniques described herein are not limited in this respect.

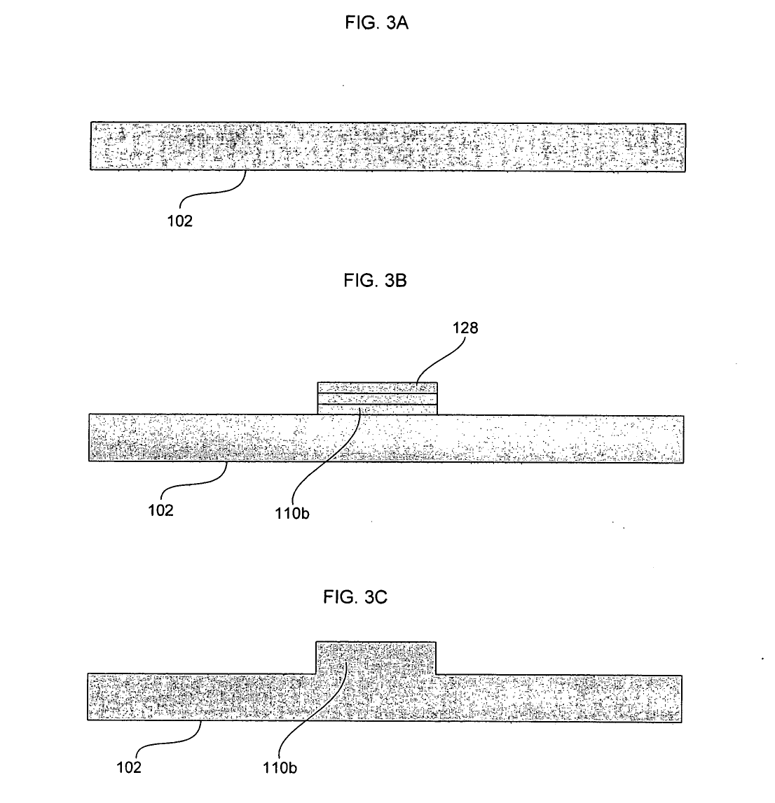

In an alternative embodiment, as illustrated in the schematics of FIGS. 3A-3C, a protrusion 110b may be fabricated by plating a substrate 102 with at least one, but possibly more, layers 128 (e.g., metal layers, such as copper and/or aluminum layers). The layers may be affixed to the substrate 102 by any process known to those of skill in the art. For example, the layers may be attached through solder or a thermally and/or electrically conductive adhesive. Alternatively, one or more layers 128 may be electro-plated onto the substrate 102 so as to form the protrusion 10b. Protrusion 10b may be flush mount with electrical contacts 104 as shown in FIG. 1. Protrusion 110b can provide effective thermal communication with the light-emitting die, such that heat generated by the light-emitting can be effectively conducted through the protrusion and ultimately through to the remaining portion of the base (e.g., the substrate 102) and to the surroundings. The substrate 102, or any other part of the supporting base, may be thermally coupled to an external heat sink, for example via direct contact, to facilitate the conduction of heat to the surroundings.

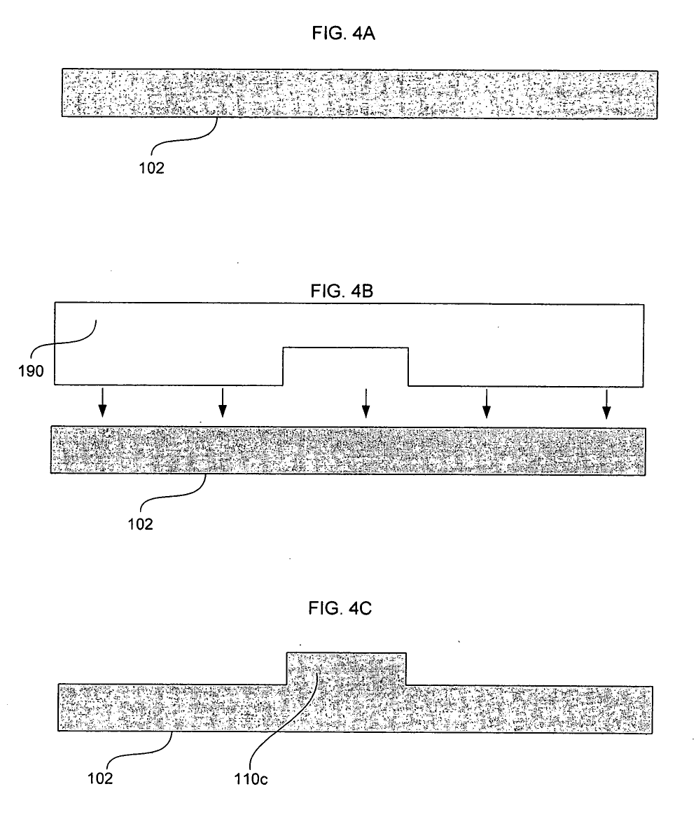

In an alternative embodiment, as shown in FIGS. 4A-4C, a protrusion may be formed using a typical stamping and/or sintering process known to those of ordinary skill in the art. A stamping or sintering process may involve providing a material for a substrate 102, either as a slab of material or as a powder. For a stamping process, a slab of material may be provided for the substrate. For a sintering process, a powdered material may be provided. A stamp or mold 190 may be provided having one or more depressions that may have a shape desired for the protrusion. The stamp or mold 190 may be applied to the substrate 102 so as to form protrusion 110c. For a stamping process, pressure may be applied to substrate 102 via a stamp 190 so as to form the protrusion 110c. For a sintering process, pressure and heat may be applied to a mold 190 holding a powdered material (e.g., a powdered metal, such as powdered copper and/or aluminum) so to compact the powder and form a solid structure having the desired protruding portions, namely protrusion 110c.

In other embodiments, a protrusion comprising a thermally conductive material different than the material of the substrate may extend through the aperture to contact the substrate and form a part of the thermally conductive pathway. The thermally conductive material may be formed of any suitable material and in any suitable way. In one such embodiment, one or more diamond layers (e.g., synthetic diamond) may extend through the aperture to form part of the thermally conductive pathway. Diamond layers may be disposed, for example using a coating process, over one or more layers (e.g., metal layers, such as copper or aluminum layers) that may also extend through the aperture. Such processes can include chemical vapor deposition (CVD), physical vapor deposition (PVD), or any other suitable coating or deposition process known to those of ordinary skill in the art. In some embodiments, a thermally conductive coating may be formed on protrusion 110a, 110b, or 110c. In one such embodiment, protrusion 110a, 110b, or 110c may be coated with a diamond coating. Diamond coating layers may be disposed on other layers in any suitable manner, including but not limited to, using a synthetic diamond coating processes, as is known in the art. Other variations would be known to those of ordinary skill in the art.

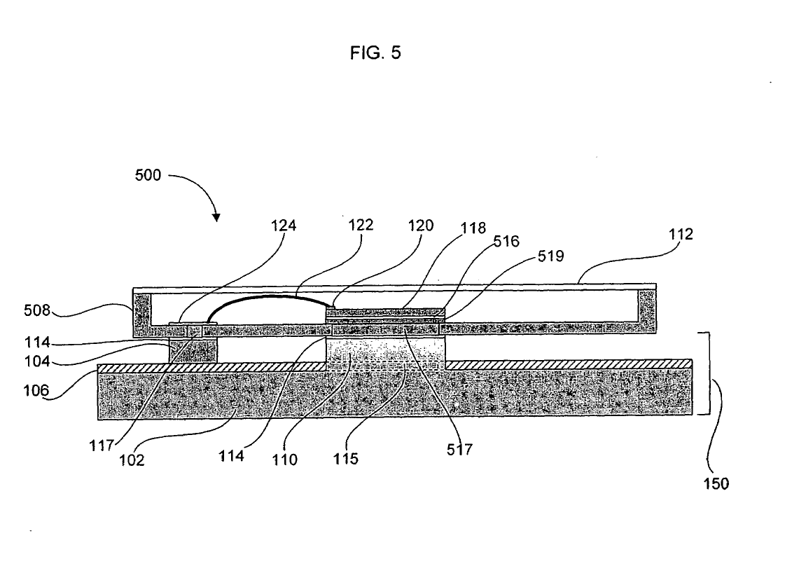

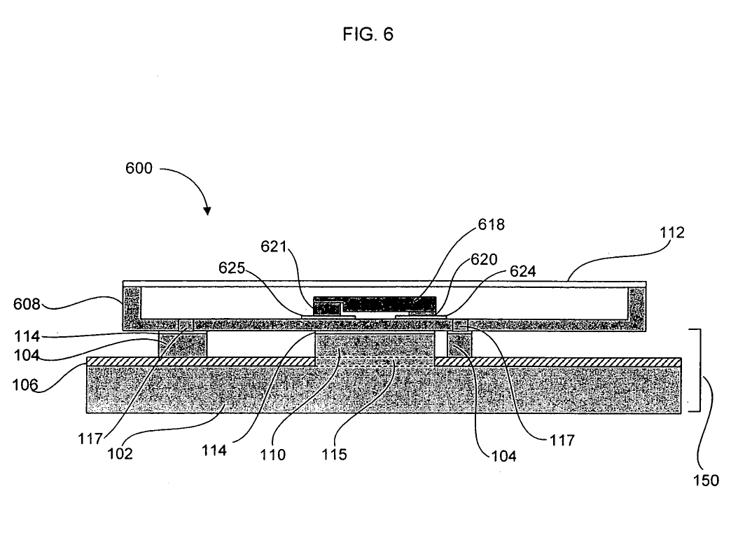

Any number of modifications may be made to the light-emitting device assembly of FIG. 1A, as shown in the embodiments of FIG. 5 and FIG. 6. FIG. 5 illustrates a light-emitting device assembly 500 wherein a protrusion 110 is also electrically conductive, in addition to thermally conductive, in accordance with one embodiment. Assembly 500 may include a package 508 that can include an electrical via 517 that extends through the package 508, wherein the electrical via 517 may be disposed between the protrusion 110 and the light-emitting die 118. Electrical via 517 may be one or more metal-filled vias (e.g., tungsten-filled vias) that allow electrical coupling between an exterior surface of the package and an interior surface of the package.

A backside of light-emitting die 118 may be electrically coupled to a p-contact 519. The light-emitting die 118 may be attached to the p-contact with an electrically conductive attachment material 516. The electrically conductive attachment material 516 may include solder (e.g., an alloy between two or more metals such as gold, germanium, tin, indium, lead, silver, molybdenum, palladium, antimony, zinc, etc.), electrical tape, or any other electrically conductive material. The p-contact 519 may be electrically coupled to the electrical via 517 of the package. Furthermore, the package can be attached to the base 150 by solder attach 114, which may also be electrically conductive. When part or all of protrusion 110 and part or all of substrate 102 are electrically conductive, for example when part or all of protrusion 110 and substrate 102 are formed of a metal (e.g., copper), an electrical contact to the light-emitting die 118 may be achieved by electrically contacting substrate 102.

FIG. 6 illustrates a light-emitting device assembly 600 including a light-emitting die flip-chip bonded to a package 608, in accordance with one embodiment. Light-emitting die 618 can include one or more n-electrical bond pads 620 contacting the n-side semiconductor layer of the light-emitting die 618 and one or more p-electrical bond pads 621 contacting the p-side semiconductor layer of the light-emitting die 618. Both the n-electrical contact pad and the p-electrical contact pad can be disposed on the same side of the light-emitting die. Light-emitting die 618 may have a recessed surface portion (e.g., an etched portion) having a depth that exposes an underlying semiconductor layer of the light-emitting die, thereby allowing the p-type electrical bond pads 621 to contact the underlying p-type semiconductor layer of the light-emitting die. Alternatively, if the semiconductor stack has an underlying n-type semiconductor layer, the underlying n-type semiconductor layer may be contacted via a recessed surface portion.

Package 608 may include n-contact 624 and p-contact 625, and light-emitting die 618 may be flip-chip bonded to n-contact 624 and p-contact 625. N-electrical bond pad 620 may be bump-bonded to the n-contact 624 and the p-electrical bond pad 621 may be bump-bonded to p-contact 625. N-contact 624 and p-contact 625 may be electrically coupled to the exterior of the package 608 by any suitable contacting technique, as the techniques presented herein are not limited in this respect. In one embodiment, n-contact 624 and p-contact 625 may extend laterally (not shown) so as to electrically couple to respective electrical vias 117, such as metal-filled vias, for the n- and p-contacts. Alternatively, n-contact 624 and/or p-contact 625 may be contacted externally via wire bonds, for example through holes (not shown) in window 112 and/or the frame of package 608. Alternatively, package 608 may include electrical vias in the frame supporting the window 112 (not shown) and n-contact 624 and/or p-contact 625 may be wire-bonded to these electrical vias in the frame. In such contacting schemes, electrical vias 117 and electrical contacts 104 shown in FIG. 6 need not necessarily be included in the assembly. Furthermore, layer 106 need not necessarily be an electrically insulating layer.

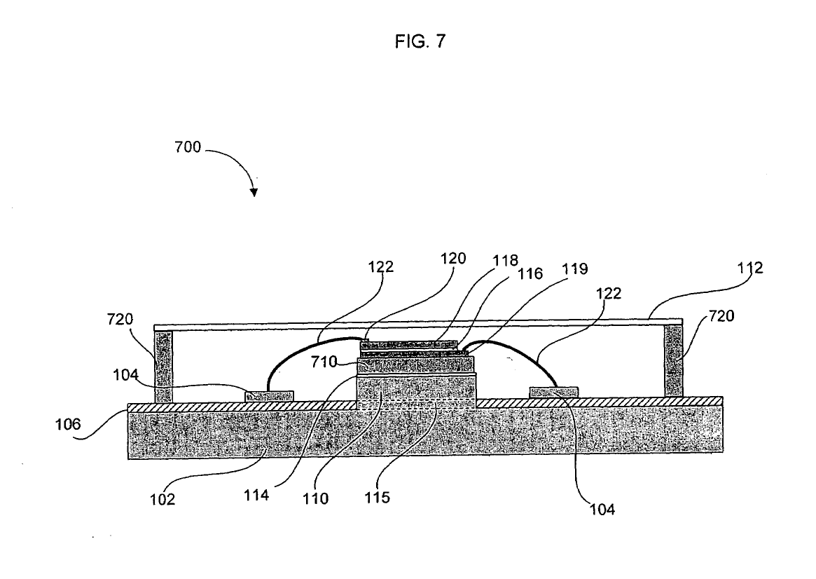

FIG. 7 illustrates a light-emitting device assembly 700 that is free of a package, separate from the base, for light-emitting die 118, in accordance with one embodiment. In one such embodiment, light-emitting die 118 may be attached to a mount 710 that may be directly mounted on protrusion 110 by attachment material 114. Mount 710 may be formed of any suitable material, including a thermally conductive material and electrically insolating, such as aluminum nitride. Alternatively, mount 710 may be electrically conductive. In such instances, a backside electrical contact to the light-emitting die 118 may be achieved. In another embodiment, light-emitting die 118 may be directly mounted on protrusion 110 and mount 710 is absent. An optional frame 720 and window 112 disposed on the frame 720 may surround the light-emitting die 118. Optional frame 720 and/or window 112 may be provided to protect light-emitting die 118, electrical contacts 104, and/or wire bonds 122. Optional frame 720 can be attached to the base using any suitable attachment method, for example using any attachment material.

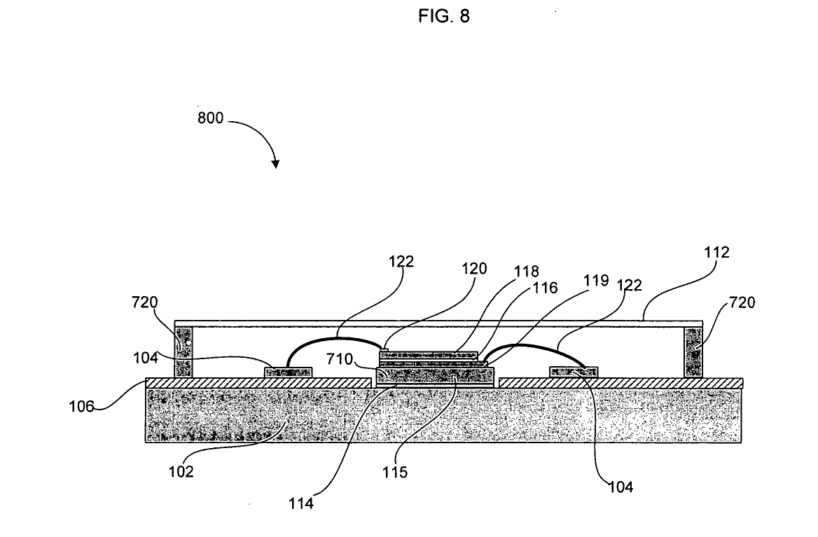

In some embodiments, protrusion 110 may be absent and mount 710 may be directly attached to the base by attachment material 114. FIG. 8 illustrates one such embodiment, wherein a light-emitting device assembly 800 includes mount 710 attached directly to supporting substrate 102. In such an embodiment, a region of the base on which mount 710 is attached may be part of substrate 102. Layer 106 may be a dielectric layer that provides electrical isolation for contacts 104. Layer 106 may also have a lower thermal conductivity than the region of substrate 102 on which mount 710 is attached. The region of the substrate 102 on which the mount is attached therefore comprises a region of higher thermal conductivity as compared to layer 106 that can define an aperture in which mount 710 resides. As illustrated in FIG. 8, the region of the base possessing a high thermal conductivity on which mount 710 is attached may be recessed relative the lower thermal conductivity region of the base (e.g., the region defined by layer 106). Alternatively, as previously described, the base may include a protrusion extending through the aperture, and defining the higher thermal conductivity region of the base. The protrusion may be elevated above layer 106, resulting in the higher thermal conductivity region being elevated above the lower thermal conductivity region defined by layer 106. Alternatively, the protrusion may be flush with layer 106, resulting in the higher thermal conductivity region being flush with the lower thermal conductivity region defined by layer 106.

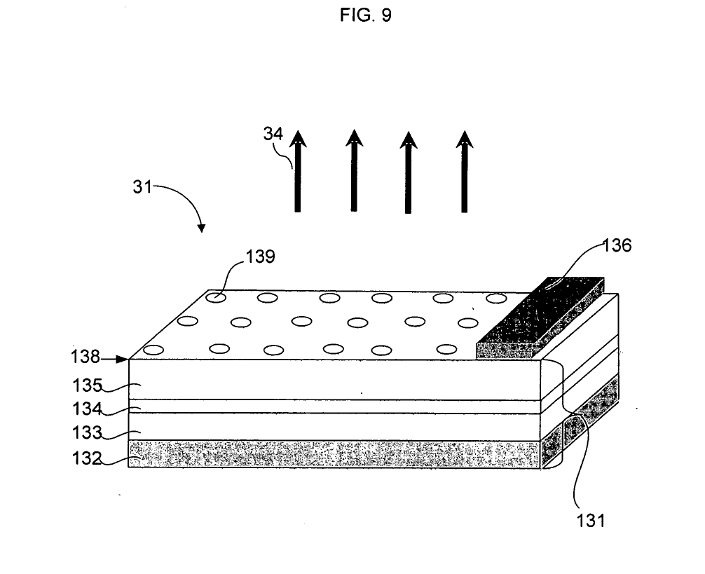

FIG. 9 illustrates an LED die that may be the light-generating component of the light-emitting device, in accordance with one embodiment. It should also be understood that various embodiments presented herein can also be applied to other light-emitting devices, such as laser diodes, and LEDs having different structures. The LED 31 shown in FIG. 9 comprises a multi-layer stack 131 that may be disposed on support structure 102 as shown in FIG. 1. The multi-layer stack 131 can include an active region 134 which is formed between n-doped layer(s) 135 and p-doped layer(s) 133. The stack can also include an electrically conductive layer 132 which may serve as a p-side contact, which can also serve as an optically reflective layer. An n-side contact pad 136 is disposed on layer 135. It should be appreciated that the LED is not limited to the configuration shown in FIG. 4, for example, the n-doped and p-doped sides may be interchanged so as to form a LED having a p-doped region in contact with the contact pad 136 and an n-doped region in contact with layer 132. As described further below, electrical potential may be applied to the contact pads which can result in light generation within active region 134 and emission of at least some of the light generated through an emission surface 138. As described further below, openings 139 may be defined in a light-emitting interface (e.g., emission surface 138) to form a pattern that can influence light emission characteristics, such as light extraction and/or light collimation. It should be understood that other modifications can be made to the representative LED structure presented, and that embodiments are not limited in this respect.

The active region of an LED can include one or more quantum wells surrounded by barrier layers. The quantum well structure may be defined by a semiconductor material layer (e.g., in a single quantum well), or more than one semiconductor material layers (e.g., in multiple quantum wells), with a smaller electronic band gap as compared to the barrier layers. Suitable semiconductor material layers for the quantum well structures can include InGaN, AlGaN, GaN and combinations of these layers (e.g., alternating InGaN/GaN layers, where a GaN layer serves as a barrier layer). In general, LEDs can include an active region comprising one or more semiconductors materials, including III-V semiconductors (e.g., GaAs, AlGaAs, AlGaP, GaP, GaAsP, InGaAs, InAs, InP, GaN, InGaN, InGaAlP, AlGaN, as well as combinations and alloys thereof), II-VI semiconductors (e.g., ZnSe, CdSe, ZnCdSe, ZnTe, ZnTeSe, ZnS, ZnSSe, as well as combinations and alloys thereof), and/or other semiconductors. Other light-emitting materials are possible such as quantum dots or organic light-emission layers.

The n-doped layer(s) 135 can include a silicon-doped GaN layer (e.g., having a thickness of about 4000 nm thick) and/or the p-doped layer(s) 133 include a magnesium-doped GaN layer (e.g., having a thickness of about 40 nm thick). The electrically conductive layer 132 may be a silver layer (e.g., having a thickness of about 100 nm), which may also serve as a reflective layer (e.g., that reflects upwards any downward propagating light generated by the active region 134). Furthermore, although not shown, other layers may also be included in the LED; for example, an AlGaN layer may be disposed between the active region 134 and the p-doped layer(s) 133. It should be understood that compositions other than those described herein may also be suitable for the layers of the LED.

As a result of openings 139, the LED can have a dielectric function that varies spatially according to a pattern which can influence the extraction efficiency and/or collimation of light emitted by the LED. In the illustrative LED 31, the pattern is formed of openings, but it should be appreciated that the variation of the dielectric function at an interface need not necessarily result from openings. Any suitable way of producing a variation in dielectric function according to a pattern may be used. For example, the pattern may be formed by varying the composition of layer 135 and/or emission surface 138. The pattern may be periodic (e.g., having a simple repeat cell, or having a complex repeat super-cell), periodic with de-tuning, or non-periodic. As referred to herein, a complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimedean patterns. In some embodiments, a complex periodic pattern can have certain openings with one diameter and other openings with a smaller diameter. As referred to herein, a non-periodic pattern is a pattern that has no translational symmetry over a unit cell that has a length that is at least 50 times the peak wavelength of light generated by active region 134. Examples of non-periodic patterns include aperiodic patterns, quasi-crystalline patterns, Robinson patterns, and Amman patterns.

In certain embodiments, an interface of a light-emitting device is patterned with openings which can form a photonic lattice. Suitable LEDs having a dielectric function that varies spatially (e.g., a photonic lattice) have been described in, for example, U.S. Pat. No. 6,831,302 B2, entitled “Light Emitting Devices with Improved Extraction Efficiency,” filed on Nov. 26, 2003, which is herein incorporated by reference in its entirety. A high extraction efficiency for an LED implies a high power of the emitted light and hence high brightness which may be desirable in various optical systems.

It should also be understood that other patterns are also possible, including a pattern that conforms to a transformation of a precursor pattern according to a mathematical function, including, but not limited to an angular displacement transformation. The pattern may also include a portion of a transformed pattern, including, but not limited to, a pattern that conforms to an angular displacement transformation. The pattern can also include regions having patterns that are related to each other by a rotation. A variety of such patterns are described in U.S. patent application Ser. No. 11/370,220, entitled “Patterned Devices and Related Methods,” filed on Mar. 7, 2006, which is herein incorporated by reference in its entirety.

Light may be generated by the LED as follows. The p-side contact layer can be held at a positive potential relative to the n-side contact pad, which causes electrical current to be injected into the LED. As the electrical current passes through the active region, electrons from n-doped layer(s) can combine in the active region with holes from p-doped layer(s), which can cause the active region to generate light. The active region can contain a multitude of point dipole radiation sources that generate light with a spectrum of wavelengths characteristic of the material from which the active region is formed. For InGaN/GaN quantum wells, the spectrum of wavelengths of light generated by the light-generating region can have a peak wavelength of about 445 nanometers (nm) and a full width at half maximum (FWHM) of about 30 nm, which is perceived by human eyes as blue light. The light emitted by the LED may be influenced by any patterned interface through which light passes, whereby the pattern can be arranged so as to influence light extraction and/or collimation.

In other embodiments, the active region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 μm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

In certain embodiments, the LED may emit light having a high power. As previously described, the high power of emitted light may be a result of a pattern that influences the light extraction efficiency of the LED. For example, the light emitted by the LED may have a total power greater than 0.5 Watts (e.g., greater than 1 Watt, greater than 5 Watts, or greater than 10 Watts). In some embodiments, the light generated has a total power of less than 100 Watts, though this should not be construed as a limitation of all embodiments. The total power of the light emitted from an LED can be measured by using an integrating sphere equipped with spectrometer, for example a SLM12 from Sphere Optics Lab Systems. The desired power depends, in part, on the optical system that the LED is being utilized within. For example, a display system (e.g., a LCD system) may benefit from the incorporation of high brightness LEDs which can reduce the total number of LEDs that are used to illuminate the display system.

The light generated by the LED may also have a high total power flux. As used herein, the term “total power flux” refers to the total power divided by the emission area. In some embodiments, the total power flux is greater than 0.03 Watts/mm², greater than 0.05 Watts/mm², greater than 0.1 Watts/mm², or greater than 0.2 Watts/mm². However, it should be understood that the LEDs used in systems and methods presented herein are not limited to the above-described power and power flux values.

In some embodiments, the LED may be associated with a wavelength-converting region (not shown). The wavelength-converting region may be, for example, a phosphor region. The wavelength-converting region can absorb light emitted by the light-generating region of the LED and emit light having a different wavelength than that absorbed. In this manner, LEDs can emit light of wavelength(s) (and, thus, color) that may not be readily obtainable from LEDs that do not include wavelength-converting regions.

As used herein, an LED may be an LED die, a partially packaged LED die, or a fully packaged LED die. It should be understood that an LED may include two or more LED dies associated with one another, for example a red-light emitting LED die, a green-light emitting LED die, a blue-light emitting LED die, a cyan-light emitting LED die, or a yellow-light emitting LED die. For example, the two or more associated LED dies may be mounted on a common package. The two or more LED dies may be associated such that their respective light emissions may be combined to produce a desired spectral emission. The two or more LED dies may also be electrically associated with one another (e.g., connected to a common ground).

When a structure (e.g., layer, region) is referred to as being “on”, “over” “overlying” or “supported by” another structure, it can be directly on the structure, or an intervening structure (e.g., layer, region) also may be present. A structure that is “directly on” or “in contact with” another structure means that no intervening structure is present.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A light-emitting device assembly comprising:
a light-emitting device; and
a base supporting the light-emitting device, the base comprising a protrusion extending in the direction of the light-emitting device, and
wherein a thermally conductive pathway extends between the light-emitting device and the base, such that the thermally conductive pathway includes the protrusion.

2. The assembly of claim 1, further comprising a package supporting the light-emitting device, and wherein the package is supported by the base.

3. The assembly of claim 1, wherein the assembly is free of a package for the light-emitting device.

4. The assembly of claim 1, the base further comprising a thermally conductive substrate, wherein the protrusion is disposed on a region of the thermally conductive substrate.

5. The assembly of claim 4, the base further comprising a layer disposed on part of the thermally conductive substrate.

6. The assembly of claim 5, wherein the protrusion extends through at least one opening in the layer.

7. The assembly of claim 5, wherein the layer is electrically insulating.

8. The assembly of claim 1, wherein the protrusion is electrically conductive.

9. The assembly of claim 1, wherein the light-emitting device is an LED.

10. The assembly of claim 9, wherein the LED comprises a photonic lattice.

11. The assembly of claim 9, wherein the LED is configured to emit light having a power of at least 0.5 Watts.

12. The assembly of claim 1, wherein the light-emitting device comprises a multi-layer stack of materials including a light-generating region, and a first layer supported by the light-generating region, a surface of the first layer being configured so that light generated by the light-generating region can emerge from the light-emitting device via the surface of the first layer; and a material in contact with the surface of the first layer, the material having an index of refraction less than about 1.5.

13. The assembly of claim 12, wherein the surface of the first layer has a dielectric function that varies spatially according to a nonperiodic pattern.

14. The assembly of claim 1, wherein the base further comprises a first electrical contact.

15. The assembly of claim 14, wherein the light-emitting device comprises a light-emitting die, and wherein a first portion of the light-emitting die is electrically coupled to the first electrical contact of the base.

16. The assembly of claim 15, wherein the base further comprises a second electrical contact, and wherein a second portion of the light-emitting die is electrically coupled to the second electrical contact of the base.

17. The assembly of claim 2, wherein the base further comprises a first electrical contact.

18. The assembly of claim 17, wherein the package further comprises a first electrical via electrically coupled to the first electrical contact of the base.

19. The assembly of claim 18, wherein the light-emitting device comprises a light-emitting die, and wherein a first portion of the light-emitting die is electrically coupled to the first electrical via of the package.

20. The assembly of claim 19, wherein package further comprises a second electrical via electrically coupled to a second portion of the light-emitting die.

21. The assembly of claim 20, wherein the second electrical via of the package is electrically coupled to the protrusion.

22. The assembly of claim 20, wherein the base further comprises a second electrical contact, and wherein the second electrical via of the package is electrically coupled to the second electrical contact of the base.

23. The assembly of claim 2, wherein a portion of the package forms part of the thermally conductive pathway.

24. The assembly of claim 1, wherein the thermally conductive pathway has a minimum thermal conductivity of greater than about 50 W/m*K.

25. The assembly of claim 1, wherein the thermally conductive pathway has a minimum thermal conductivity of greater than about 200 W/m*K.

26. A light-emitting device assembly comprising:
a light-emitting device; and
a base comprising an electrically insulating portion and a thermally conductive portion, wherein the electrically insulating portion of the base comprises an electrically insulating material layer, and wherein the electrically insulating material layer is disposed over a portion of the thermally conductive portion of the base, and
wherein a thermally conductive pathway extends between the light-emitting device and the thermally conductive portion of the base.

27. The assembly of claim 26, further comprising a package supporting the light-emitting device, and wherein the package is supported by the base.

28. The assembly of claim 26, wherein the assembly is free of a package for the light-emitting device.

29. The assembly of claim 26, wherein the thermally conductive portion of the base comprises a protrusion extending in the direction of the light-emitting die, and wherein the thermally conductive pathway includes the protrusion.

30. The assembly of claim 29, wherein the protrusion extends through at least one opening in the electrically insulating portion of the base.

31. The assembly of claim 26, wherein the thermally conductive portion of the base is electrically conductive.

32. The assembly of claim 26, wherein the electrically insulating material layer comprises a dielectric material layer.

33. A light-emitting device assembly comprising:
a light-emitting device;
a support substrate; and
a dielectric material layer disposed on the support substrate and defining an aperture,
wherein a thermally conductive pathway extends through the aperture between the support substrate and the light-emitting device.

34. A light-emitting device assembly comprising:
a light-emitting device;
a base comprising a first region having a first thermal conductivity and a second region having a second thermal conductivity, wherein the first thermal conductivity is larger that the second thermal conductivity, wherein the second region defines an aperture within which at least a portion of the first region resides, and
wherein a thermally conductive pathway extends between the first region of the base and the light-emitting device.

35. The assembly of claim 34, wherein the first region of the base is elevated above the second region of the base.

36. The assembly of claim 34, wherein the first region of the base is flush with the second region of the base.

37. The assembly of claim 34, wherein the second region of the base is elevated above the first region of the base.

38. A method of fabricating a light-emitting device assembly, the method comprising:
providing a base comprising a thermally conductive portion, wherein the thermally conductive portion of the base comprises a protrusion;
providing a light-emitting device; and
forming a thermally conductive pathway that extends between the light-emitting device and the thermally conductive portion of the base, such that the thermally conductive pathway includes the protrusion.

39. The method of claim 38, wherein providing the base comprises:
providing a substrate; and
disposing the protrusion over a portion of the substrate.

40. The method of claim 39, wherein disposing the protrusion comprises electroplating at least one thermally conductive layer so as to form at least part of the protrusion.

41. The method of claim 38, wherein providing the base comprises:
providing a thermally conductive substrate; and
removing a portion of the thermally conductive substrate to form the protrusion.

42. The method of claim 38, wherein providing the base comprises:
providing a thermally conductive substrate; and
stamping the thermally conductive substrate so as to form the protrusion.

43. The method of claim 38, wherein providing the base comprises sintering a thermally conductive material so as to form a thermally conductive substrate and the protrusion disposed thereon.
